(19) United States
(12) Patent Application Publication
(10) Pub. No.: US 2008/0112137 A1
(43) Pub. Date: May 15, 2008

(54) COOLING DEVICE FOR INVERTER AND LDC ELEMENTS FOR HEV

(76) Inventor: Kang Hoon KO, Suwon-si (KR)

Correspondence Address: MORGAN, LEWIS & BOCKIUS LLP (SF), 2 PALO ALTO SQUARE, 3000 El Camino Real, Suite 700, PALO ALTO, CA, 94306, US

(21) Appl. No.: 11/839,288

(22) Filed: Aug. 15, 2007

(30) Foreign Application Priority Data
Nov. 12, 2006 (KR) 10-2006-0125258

(51) Int. Cl. H05K 7/20

(52) U.S. Cl. 361/700; 903/904

(57) ABSTRACT

The present invention relates to a cooling device for inverter and DC/DC converter (LDC) elements for hybrid electric vehicle (HEV) and, more particularly, to a cooling device for inverter and LDC elements for HEV that enhances the cooling efficiency by applying a cooling device that uses a heat pipe principle to convect coolant to an inverter system that radiates heat of high temperature. For this purpose, the present invention provides a cooling device including a heat sink attached closely to inverter and LDC elements generating heat and a plurality of heat sink fins formed in a body on one surface of the heat sink, wherein the cooling device is characterized in that a coolant convection space is formed in the heat sink; a porous material made of a heat conductive material is attached on the whole inner surface of the coolant convection space; coolant is filled in the coolant convection space so that the coolant in the coolant convection space is convected from the substantial middle of the coolant convection space to both distal sides thereof by heat diffusion generated from the elements to radiate heat and then returns to the substantial middle portion.

### CROSS-REFERENCE TO RELATED APPLICATION

This application claims the benefit under 35 U.S.C.§119(a) on Korean Patent Application No. 10-2006-0125258, filed on Dec. 11, 2006, the entire disclosure of which is incorporated herein by reference.

### BACKGROUND OF THE INVENTION

1. Field of the Invention

The present invention relates to a cooling device for inverter and DC/DC converter (LDC) elements for a hybrid electric vehicle (HEV). More particularly, the present invention relates to a cooling device for inverter and LDC elements for a HEV, in which a heat pipe construction is adopted for enhancing the cooling performance.

2. Description of Related Art

In general, a hybrid electric vehicle (hereinafter “HEV”) has two power sources including an internal combustion engine and an electric motor empowered by a battery. By using the electric motor as a supplementary power source when starting or accelerating a vehicle, it is possible to improve fuel efficiency of the vehicle.

The hybrid electric vehicle includes an LDC, i.e., a DC/DC converter that converts electric power of a high voltage battery into a direct current. That is, the LDC switches a direct current to an alternating current, boosts or drops the alternating current using coil, transformer, capacitance, etc., rectifies the resulting alternating current to a direct current and supplies electricity suitable for voltages used in respective electrical loads.

Moreover, in case of the hybrid electric vehicle and a fuel cell vehicle, a high power inverter system for the operation of the electric motor is required. Such an inverter system inverting a D/C energy of a battery to an A/C required for driving the electric motor radiates a great deal of heat. Accordingly, in order to maintain an appropriate operation state of the inverter system, it is necessary to keep the temperature of the inverter within a temperature limit that an IC built therein endures.

Furthermore, in case of an inverter used in a vehicle, various attempts aimed at reducing size and weight of the inverter against its efficiency have been made. But the surface area in an air cooling method is required large, whereas, the sizes of elements generating heat become reduced for reason of cost, etc. Accordingly, the heat radiation efficiency of a heat sink becomes more important.

Accordingly, as depicted in FIG. 8, a fan 101 and a duct 102, in general, are established to make air flow smoothly in a battery assembly 100 mounted in a trunk room of a vehicle and a cooling device having a separate heat sink 10 structure is arranged in an inverter system 104.

Moreover, as depicted in FIG. 6, the conventional cooling device has a structure in which a heat sink 10 made of aluminum is attached t closely to heat generating elements 50, and a plurality of heat sink fins 20 are formed in a body on the bottom surface of the heat sink 10.

Accordingly, the heat generated from the heat generating elements 50 is radiated to the outside through the heat sink 10 and the heat sink fins 20 made of aluminum.

However, since the heat generated from the elements 50 is radiated as diffused heat, the diffused heat cannot be radiated uniformly through the whole heat sink 10 and its fins 20, but radiated at local areas of the heat sink and fins adjacent to the elements, thus lowering the cooling efficiency of the inverter system to cause a deterioration of the system performance.

Taking these problems into consideration, various attempts aimed at controlling the diffusion heat from the heat generating elements by adjusting the thickness of the heat sink has been tried. However, as the size of the heat generating element is small, its thickness becomes larger and thereby results in an increase in weight and cost and causes the increase of a local temperature in the heat sink.

Meanwhile, Japanese Patent Publication No. 2002-119070 has disclosed a cooling device for an inverter for vehicle that increases the cooling efficiency by coolant for cooling a heat sink, in which a radiator includes a plurality of fins formed on the surface thereof, an inlet and outlet for flowing in and out the coolant therein, and where the heat sink and the radiator are formed in a body. Moreover, Korean Utility Model Publication No. 20-1999-0038391 has disclosed an inverter provided on the top surface of a cooling plate having a predetermined thickness, in which a coolant path, of which a top portion is formed open, including an inlet portion and an outlet portion through which coolant is circulated, is established to prevent the overheat of the inverter. However, the above conventional arts have a drawback in that a separate coolant circulation device is required to use the circulation of the coolant.

The information disclosed in this Background of the Invention section is only for enhancement of understanding of the background of the invention and should not be taken as an acknowledgement of any from of suggestion that this information forms the prior art that is already known to a person skilled in the art.

### SUMMARY OF THE INVENTION

Accordingly, the present invention has been contrived to solve the above-described drawbacks. In one aspect, the present invention provides a cooling device for inverter and LDC elements for hybrid electric vehicle so as to enhance the efficiency of cooling performance by adopting a heat pipe construction having a convection flow of coolant.

In an embodiment, the present invention provides a cooling device for inverter and LDC elements for a hybrid electric vehicle, which comprises a heat sink closely attached to the inverter and LDC elements that generate heat; a plurality of heat sink fins extending from the heat sink at an opposite side of the inverter and LDC elements; a coolant convection space structurally defined in the heat sink; and coolant being filled in the coolant convection space. The coolant filled in the coolant convection space is configured to transfer heat by evaporating while absorbing a latent heat at a substantial center of the coolant convection space where the inverter and LDC elements are positioned; moving toward both distal sides of the coolant convection space due to difference of vapor pressure; condensing into a form of liquid due to heat exchange at both distal sides of the coolant convection space; and thereafter returning back to the center of coolant convection space.

In a preferred embodiment, a porous material made of a heat conductive material is attached on the whole inner surface of the coolant convection space.

In a further preferred embodiment, the porous material is made of an aluminum material.

Cooling device for inverter and LDC elements for HEV of the present invention has other features and advantages which will be apparent from or are set forth in more detail in the accompanying drawings, which are incorporated in and form a part of this specification, and the following Detailed Description of the Invention, which together serve to explain the principles of the present invention.

### BRIEF DESCRIPTION OF THE DRAWINGS

The above and other features of the present invention will be described with reference to certain exemplary embodiments thereof illustrated the attached drawings which are given by way of illustration only, and thus are not limitative of the present invention, and wherein:

FIG. 1 is an exploded perspective view depicting a cooling device for inverter and LDC elements for hybrid electric vehicle in accordance with the present invention;

FIG. 2 is a sectional view depicting a cooling device for inverter and LDC elements for hybrid electric vehicle in accordance with the present invention;

FIG. 3 is a sectional view depicting a state before radiating heat in a cooling device for inverter and LDC elements for hybrid electric vehicle in accordance with the present invention;

FIG. 4 is a sectional view depicting a state of radiating heat in a cooling device for inverter and LDC elements for hybrid electric vehicle in accordance with the present invention;

FIG. 5 is schematic diagrams illustrating that a temperature gradient of an element having a large temperature gradient is decreased by a cooling device of the present invention;

FIG. 6 is a sectional view illustrating a conventional cooling device for inverter and LDC elements for hybrid electric vehicle;

FIGS. 7A and 7B are schematic diagrams illustrating a heat pipe principle; and

FIG. 8 is a schematic diagram illustrating a position where a cooling device for inverter and LDC elements for hybrid electric vehicle is established.

Reference numbers refer to the same or equivalent parts of the present invention throughout the several figures of the drawing.

### DETAILED DESCRIPTION OF THE INVENTION

Hereinafter, reference will now be made in detail to the preferred embodiments of the invention, examples of which are illustrated in the accompanying drawings. While the invention will be described in conjunction with the preferred embodiments, it will be understood that they are not intended to limit the invention to those embodiments. On the contrary, the invention is intended to cover alternatives, modifications and equivalents, which may be included within the spirit and scope of the invention as defined by the appended claims.

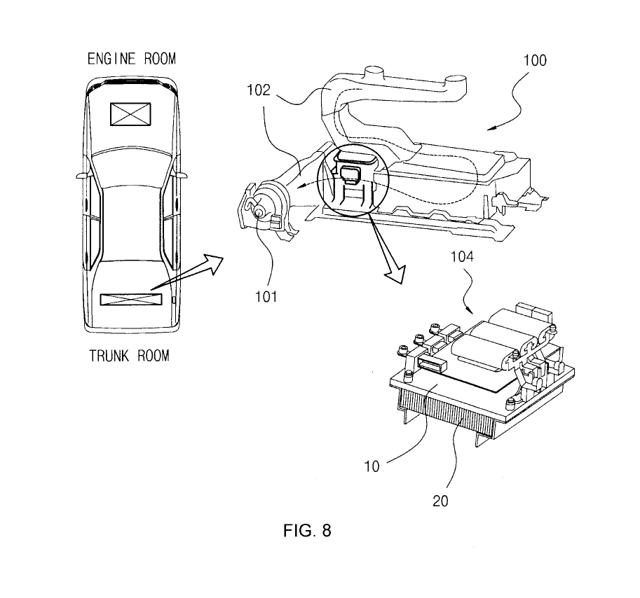

As described above, a fan and a duct are established to make air flow smoothly in a battery assembly mounted in a trunk room of a vehicle and a cooling device having a separate heat sink structure is arranged in an inverter system as shown in FIG. 8.

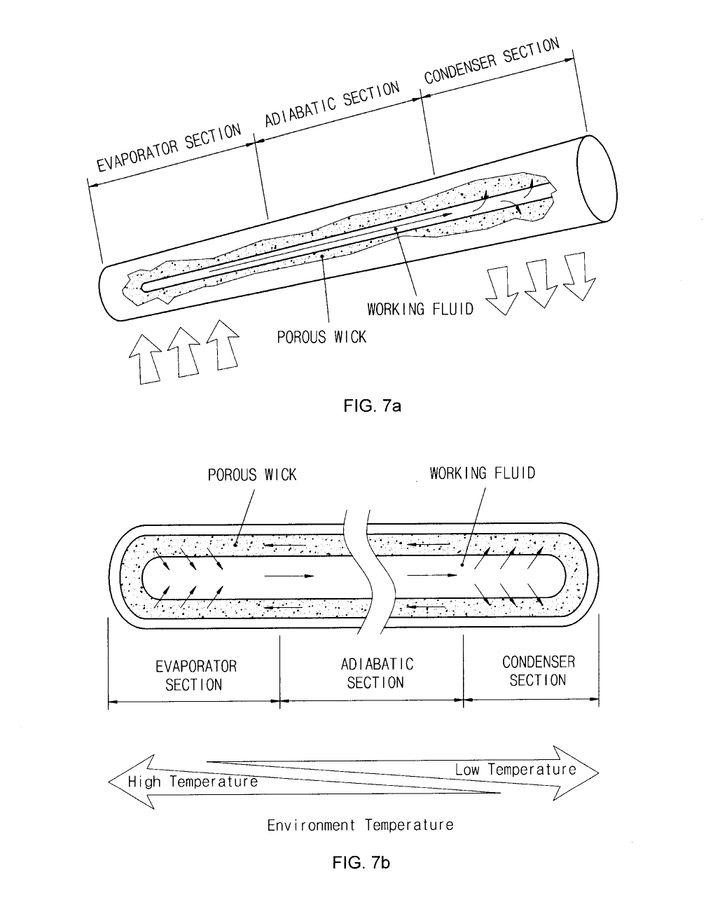

The cooling device in accordance with the present invention uses a heat transfer principle of a heat pipe comprising an evaporator section, an adiabatic section, a condenser section, a container, a porous wick and a working fluid, as depicted in FIGS. 7A and 7B.

Accordingly, if heat is applied to the evaporator section, a working fluid is evaporated to transfer heat from a heat source to the condenser section through the adiabatic section and then the working fluid is liquefied to return to the evaporator section through the porous wick. By repeating such a series of processes, the heat pipe transfers the heat from the heat source to provide a cooling effect.

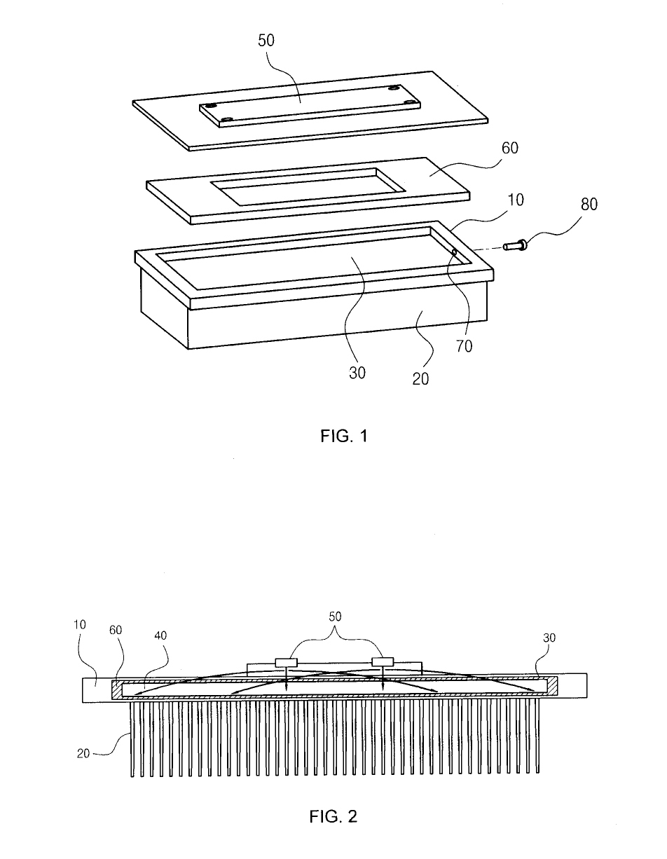

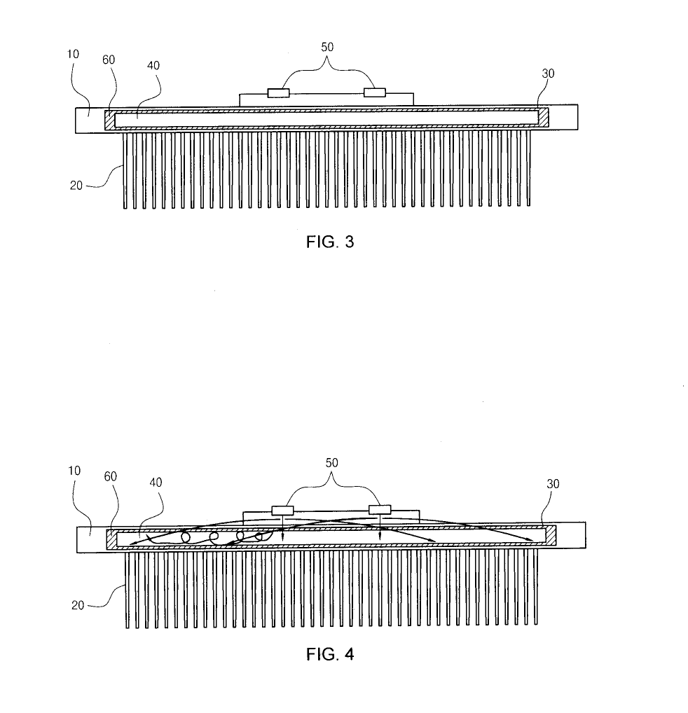

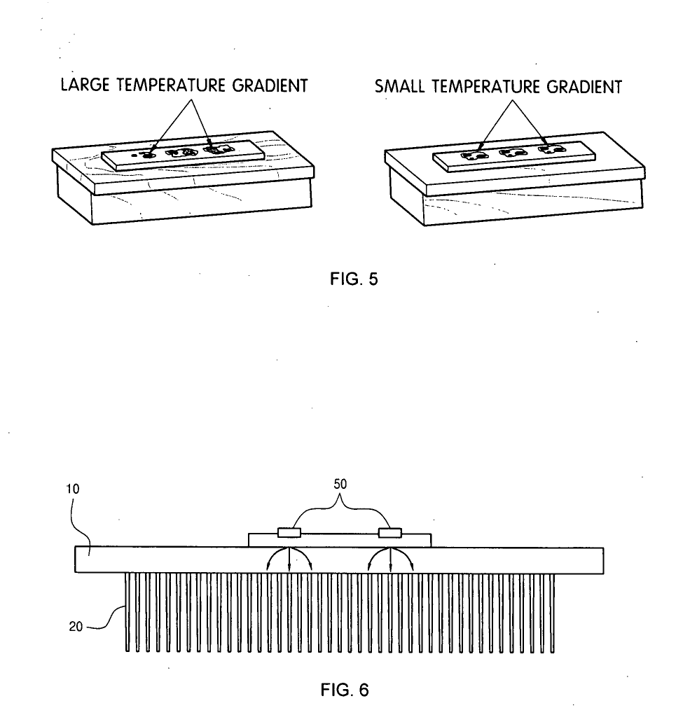

FIG. 1 is an exploded perspective view depicting a cooling device for inverter and LDC elements for hybrid electric vehicle in accordance with the present invention, and FIG. 2 is a sectional view depicting the cooling device for inverter and LDC elements for hybrid electric vehicle in accordance with the present invention.

The cooling device for inverter and LDC elements of the present invention comprises a heat sink 10 set closely to inverter and an LCD elements and a plurality of heat sink fins 20 formed in a body on one surface of the heat sink 10.

Here, a coolant convection space 30 is formed in the heat sink 10 and a working fluid, i.e., a coolant 40 is filled in the coolant convection space 30.

The coolant 40 is convected from the substantial middle portion of the coolant convection space 30 to both distal sides thereof by heat diffusion generated from heat generating elements 50, thus radiating heat and then returns to the substantial middle portion of the coolant convection space 30 through a porous material 60.

Especially, the porous material 60 made of a heat conductive material is attached on the whole inner surface of the coolant convection space 30 of the heat sink 10 and the porous material 60 is desirably made of an aluminum material in an embodiment.

Meanwhile, a drain hole 70 for a maintenance service is formed near to one side of the coolant convection space 30 of the heat sink 10 and clogged by a bolt 80.

Here, the cooling operation of the cooling device for inverter and LDC elements configured as described above will be explained as follows.

FIG. 3 is a sectional view depicting a state before radiating heat in the cooling device for inverter and LDC elements for hybrid electric vehicle in accordance with the present invention, and FIG. 4 is a sectional view depicting a state of radiating heat in the cooling device for inverter and LDC elements for hybrid electric vehicle in accordance with the present invention.

Differently from the conventional art, the cooling device using the heat pipe principle in accordance with the present invention can enhance the heat radiation performance by configuring and arranging the coolant convection space 30 in the heat sink 10 to ensure an increase of heat diffusion by using natural convection of coolant and an increase of the convection using a capillary phenomenon in the porous material 60.

The heat generated from heat elements such as the inverter and the LDC set closely to the top surface of the heat sink 10 is transferred to the coolant 40 filled in the coolant convection space 30 through an upper plate of the heat sink 10 and the thin porous material 60 therein.

Then, vaporization of the coolant 40 absorbs the latent heat of heated coolant 40 and thus the heated coolant 40 is changed into a vapor phase. Since the vapor pressure higher at the substantial middle portion of coolant convection space 30 is higher than that of the cooler distal sides of the coolant convection space 30, this pressure difference therebetween drives a movement of the coolant 40 to the peripheral portion of the coolant convection space 30.

In FIG. 4, thick arrows denote diffusion directions of heat flux generated from the heat generating elements 50 and a solid arrow denotes the coolant 40 of a vapor phase generated by heat, moving to the peripheral portion of the coolant convection space 30 by pressure difference which develops the heat diffusion. Since both distal sides of the coolant convection space 30 are cooler than the substantial middle portion of the coolant convection space 30, the coolant 40 completes the heat transfer to both distal sides of the coolant convection space 30. The vaporized coolant 40 is condensed and moves back to the substantial middle portion of the coolant convection space 30 through the porous material 60 by capillary force.

That is, the coolant 40 undergoing the vapor phase in moving away from the heat source loses its heat by heat exchange with the heat sink fins 20 formed on the bottom surface of the heat sink 10 and then is convected to the middle portion of the coolant convection space 30.

Here, the coolant 40 has a heat transfer rate of several hundred times higher conduction coefficient than the existing coolant has.

Accordingly, the cooling performance of the cooling device for inverter and LDC elements for hybrid electric vehicle in accordance with the present invention can be remarkably increased.

Moreover, the present invention can cool the heat sources of small size, i.e., the heat elements, effectively and thereby reduce the weight and size of the cooling device.

Meanwhile, as depicted in FIG. 5, in case that the heat elements having large temperature gradients would be cooled by the cooling device of the present invention, the temperature gradients also could be reduced effectively regardless of the temperature reduction of the heat sink in itself and the positions of the elements, thus lessening the limitations in the arrangement of the cooling device to provide free modifications to the design and further to extend the lifespan.

As described above, according to the cooling device for inverter and LDC elements for hybrid electric vehicle in accordance with the present invention, it is possible to enhance the cooling performance of the cooling device remarkably by configuring and arranging the coolant convection space in the heat sink so that the coolant is circulated by the convection phenomenon with the heat diffusion generated from the elements.

Moreover, the present invention can cool the heat sources of small size, i.e., the heat elements effectively and thereby reduce the weight and size of the cooling device.

Furthermore, the temperature gradients of the heat elements to be cooled could be reduced effectively regardless of the temperature reduction of the heat sink in itself and the positions of the elements, thus lessening_the limitations in the arrangement of the cooling device to provide free modifications to the design and further extending the lifespan.

As above, preferred embodiments of the present invention have been described and illustrated, however, the present invention is not limited thereto, rather, it should be understood that various modifications and variations of the present invention can be made thereto by those skilled in the art without departing from the spirit and the technical scope of the present invention as defined by the appended claims.

What is claimed is:

1. A cooling device for inverter and LDC elements for a hybrid electric vehicle, comprising:
a heat sink closely attached to the inverter and LDC elements that generate heat;
a plurality of heat sink fins extending from the heat sink at an opposite side of the inverter and LDC elements;
a coolant convection space defined in the heat sink; and
coolant being filled in the coolant convection space, wherein the coolant filled in the coolant convection space is configured to transfer heat by evaporating while absorbing a latent heat at a substantial middle portion of the coolant convection space where the inverter and LDC elements are positioned, moving toward both distal sides of the coolant convection space due to difference of vapor pressure, condensing into a form of liquid due to heat exchange at both distal side of the coolant convection space, and thereafter returning to the substantial middle portion of coolant convection space through a porous material.

2. The cooling device for inverter and LDC elements for hybrid electric vehicle as recited in claim 1,
wherein the porous material is made of an aluminum material.
